(19) United States
(12) Patent Application Publication
(10) Pub. No.: US 2010/0237913 A1
(43) Pub. Date: Sep. 23, 2010

(54) ELECTRONIC DEVICE

(75) Inventor: Naoki NISHIOKA, Kyoto-shi (JP)

Correspondence Address: MURATA MACHINERY, LTD.;(MURATEC) c/o KEATING & BENNETT LLP, 1800 Alexander Bell Drive, SUITE 200, Reston, VA, 20191, US

(73) Assignee: MURATA MACHINERY, LTD., Kyoto-shi (JP)

(21) Appl. No.: 12/717,994

(22) Filed: Mar. 5, 2010

(30) Foreign Application Priority Data
Mar. 18, 2009 (JP) 2009-066518

(51) Int. Cl. H03L 7/00

(52) U.S. Cl. 327/143

(57) ABSTRACT

An electronic device includes a first reset signal generator arranged to output a first reset signal when a power supply voltage becomes lower than or equal to a first threshold, a second reset signal generator arranged to output a second reset signal when the power supply voltage becomes lower than or equal to a second threshold lower than the first threshold, a return reset signal generator arranged to output a return reset signal based on a termination of the output of the first reset signal, a first resetting device arranged to be reset based on the first reset signal, a second resetting device arranged to be reset based on the second reset signal and the return reset signal, and a pre-processor arranged in the second resetting device to start a preliminary process of resetting based on the first reset signal.

This application claims priority under 35 U.S.C. 119 to Japanese Patent Application No. 2009-66518, filed on Mar. 18, 2009, which application is hereby incorporated by reference in its entirety.

### BACKGROUND OF THE INVENTION

1. Field of the Invention

The present invention relates to electronic devices, and more specifically, to improvements in an electronic device that performs a preliminary process of resetting based on lowering of a voltage of a power supply.

2. Description of the Related Art

A multi-functional device is an electronic device having a plurality of functions of a printer, a facsimile, a scanner and the like. When power starts to be supplied to the multi-functional device, the device is reset to prevent abnormal operation and breakage of the multi-functional device in a low voltage state. Similarly, the device is also reset when shutting off the power.

The device is reset also in a case where the power supply of the multi-functional device is cut off by blackout and the like. However, if a hard disk drive of the multi-functional device is immediately reset and the hard disk is stopped in the operating state, a disc may hit a reading head and be broken by the subsequent impact. If being reset while writing to a flash memory, data may not be normally read from the flash memory due to data corruption.

Therefore, the multi-functional device needs to perform preliminary process of resetting to prevent breakage of device, data corruption and the like at the time of power down. Specifically, the data is saved from a volatile memory to a nonvolatile flash memory or a hard disk drive to prevent loss of data, and the head of the hard disk drive is returned to a standby position to prevent breakage of the hard disk drive.

The preliminary process of resetting needs to be performed before resetting. To this end, a trigger signal instructing the start of the preliminary process of resetting first needs to be generated, and the resetting is to be performed after ensuring a sufficient period for the preliminary process of resetting. For instance, a multi-functional device is known in which the resetting process is performed after ensuring a sufficient period for the preliminary process of resetting when a power switch is pushed. In such a multi-functional device, however, a case where the power is stopped by pulling out a commercial power supply plug, and a case of blackout, etc. are not assumed, and there is a need to ensure the period for the preliminary process of resetting even in such cases.

In a conventional electronic device, there is known a technique of generating a trigger signal to start saving data at the same time as a reset signal, delaying the start of resetting by delaying the reset signal with a delay circuit, and thus ensuring the period for saving the data at the time of power down. As another conventional electronic device, there is described an electronic device for monitoring the lowering in power supply voltage due to the shutting of the power supply with a voltage monitor circuit, creating a difference between a threshold of the power supply voltage to start saving the data and a threshold of the power supply voltage to start resetting, and thereby ensuring the period for saving the data.

In the above-described electronic devices, the period for saving the data can be ensured by delaying the start of resetting by the delay circuit. However, the resetting cannot be delayed for a long period and a sufficient period may not be ensured to save the data in view of reliably resetting the device, since the speed at which the power supply voltage lowers at the time of power down is not constant.

In another conventional electronic device, a difference is created in the threshold values of the power supply voltage, and timings of outputting a signal, which becomes a trigger in saving the data, and the reset signal are shifted to ensure the period for saving the data. The data starts to be saved when the power supply voltage lowers to be smaller than or equal to a first threshold, and the device is reset when the power supply voltage lowers to be smaller than or equal to a second threshold. Thus, the data can be saved but the resetting is not performed when the power supply voltage lowers to be smaller than or equal to the first threshold but the power supply voltage recovers without lowering to be smaller than or equal to the second threshold. However, the resetting is delayed to ensure the period for performing the preliminary process of resetting such as saving data, and the device needs to be reset to prevent abnormal operation and breakage of the device after the preliminary process of resetting is performed.

### SUMMARY OF THE INVENTION

In order to overcome the problems described above, preferred embodiments of the present invention provide an electronic device that can be reset after a preliminary process of resetting is performed when a power supply is shut off. Another preferred embodiment of the present invention also provides an electronic device that is capable of saving data in a volatile storage device to a nonvolatile storage device and resetting the device when a power supply is shut off.

According to a preferred embodiment of the present invention, an electronic device includes a first reset signal generator arranged to output a first reset signal when a power supply voltage becomes lower than or equal to a first threshold; a second reset signal generator arranged to output a second reset signal when the power supply voltage becomes lower than or equal to a second threshold lower than the first threshold; a return reset signal generator arranged to output a return reset signal based on a termination of the output of the first reset signal; a first resetting device arranged to be reset based on the first reset signal; a second resetting device arranged to be reset based on the second reset signal and the return reset signal; and a pre-processor arranged in the second resetting device to start a preliminary process of resetting based on the first reset signal.

According to such a configuration, a difference is created in threshold voltages at which the device is reset, where the first resetting device is reset at an early stage if the power supply voltage lowers, and the resetting of the second resetting device is delayed to ensure a period necessary for the preliminary processing of resetting. Furthermore, since the second resetting device is reset based on the return reset signal, the second resetting device is reset if the power supply voltages lowers so as to be lower than or equal to the first threshold value even if the power supply voltage does not lower so as to be lower than or equal to the second threshold value, whereby abnormal operation, breakage, and the like of both the first resetting device and the second resetting device are prevented.

According to another preferred embodiment of the present invention, in addition to the above-described configuration, the pre-processor is arranged to start to save data held in a volatile storage device to a nonvolatile storage device based on the first reset signal.

According to such a configuration, the timing at which the second resetting device is reset is delayed to ensure a period necessary for saving the data held in the volatile storage device to the nonvolatile storage device.

According to a further preferred embodiment of the present invention, in addition to the above-described configuration, the return reset signal generator outputs the return reset signal for a constant period from the termination of the output of the first reset signal using a delay circuit.

According to such a configuration, the return reset signal can be output using a time difference at the time of output of the reset signal using the delay circuit and the reset signal not using the delay circuit, and hence the configuration of resetting the second resetting device at the time of return of the power supply voltage can be realized with a simple circuit.

According to an additional preferred embodiment of the present invention, the first resetting device is reset at an early stage, and a second threshold lower than the first threshold is given to the second resetting device to delay the resetting. The preliminary processing of resetting is started with the reset signal used in the resetting of the first resetting device as a trigger to ensure the period for performing the preliminary processing of resetting of the second resetting device.

Furthermore, although the first resetting device and the second resetting device have different power supply thresholds at which they are reset, the second resetting device is reset when the power supply voltage recovers if the first resetting device is reset. Thus, if the power supply voltage lowers to be lower than or equal to the first threshold, both the first resetting device and the second resetting device are reset even if the power supply voltage does not lower to be lower than or equal to the second threshold.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a block diagram of an electronic device 1 according to a preferred embodiment of the present invention.

FIG. 2 is a block diagram illustrating one configuration example of a return reset signal generator 103 illustrated in FIG. 1.

FIG. 3 is a graph indicating voltage change of each output terminal in FIG. 2 in a case where a power supply voltage Vdd is lowered.

FIG. 4 is a graph indicating voltage change of each output in a case where the power supply voltage Vdd of FIG. 1 is changed.

FIG. 5 is a graph indicating potential change of each output of FIG. 1.

FIG. 6 is a flow chart illustrating one example of a power supply monitoring process in the electronic device 1 of FIG. 1.

### DETAILED DESCRIPTION OF THE INVENTION

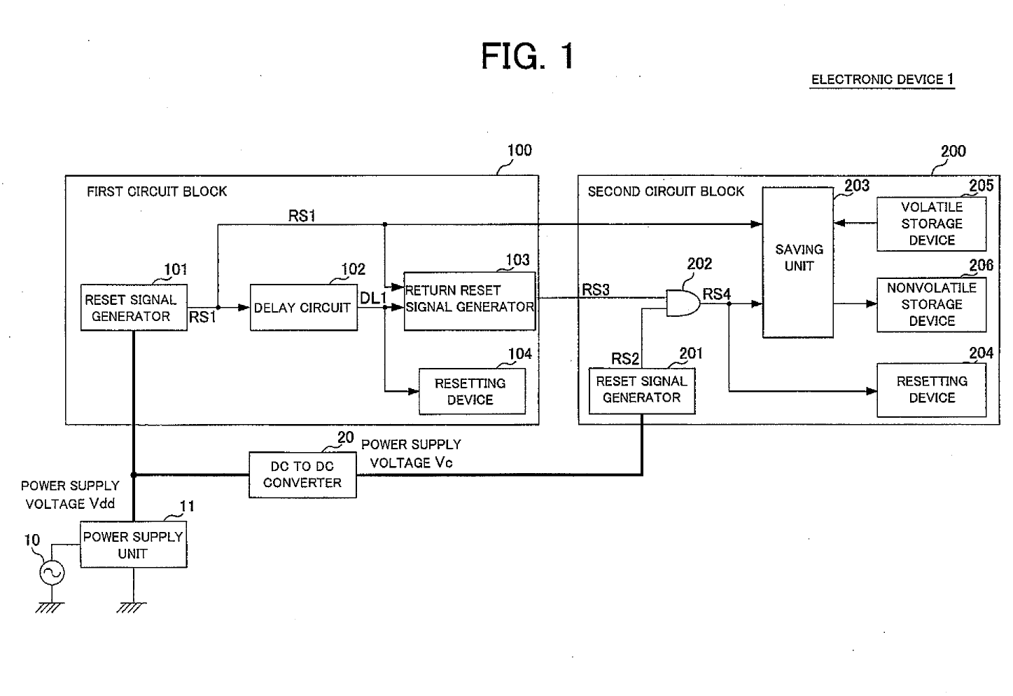

FIG. 1 is a block diagram illustrating a configuration example of an electronic device 1 according to a preferred embodiment of the present invention. The electronic device 1 preferably includes a commercial power supply 10, a power supply unit 11, a DC to DC converter 20, a first circuit block 100, and a second circuit block 200.

The power supply unit 11 preferably is a constant-voltage power supply of a voltage Vdd arranged to convert an alternating current or AC power supplied from the commercial power supply 10 to a direct current or DC power. The voltage Vdd of the power supply is normal voltage V₀, and the power supply voltage Vdd lowers from the normal voltage V₀ at the time of power down. Here, the power supply unit 11 supplies power to the first circuit block 100 and the DC to DC converter 20. The DC to DC converter 20 is a voltage conversion circuit arranged to convert the voltage of the supplied power, and outputting to the second circuit block 200. The DC to DC converter 20 converts the power supply voltage Vdd to the power supply voltage Vc lower than the Vdd, and supplies the converted voltage Vc to the second circuit block 200. The power supply voltage Vc is normal voltage V₁₀, and lowers from the voltage V₁₀ with the lowering of the power supply voltage Vdd at the time of power down. The first circuit block 100 outputs a first reset signal RS1 and a return reset signal RS3, which signals RS1 and RS3 are respectively input to the second circuit block 200. The first reset signal RS1 and the return reset signal RS3 are respectively low active signals.

The circuit block 100 preferably includes a reset signal generator 101, a delay circuit 102, a return reset signal generator 103, and a resetting device 104. The reset signal generator 101 is a reset IC arranged and programmed to monitor the power supply voltage Vdd, and to output a first reset signal RS1 when the power supply voltage Vdd lowers from the normal voltage V₀ to a threshold voltage V₁ due to shutting of the power supply, and the like. The device is reset by detecting the lowering of the power supply voltage Vdd and outputting the reset signal, whereby the abnormal operation and other malfunctions of the device can be prevented at the time of power down.

The DC to DC converter (not illustrated) converts the voltage from the power supply voltage Vdd to the power supply voltage Vc, and the converted power supply is supplied to each device other than the reset signal generator 101 of the first circuit block 100. The power of the power supply voltage Vdd is supplied to the reset signal generator 101 as is.

When the first reset signal RS1 is input, the delay circuit 102 outputs a delayed reset signal DL1, in which the first reset signal RS1 is delayed by a constant period. The return reset signal generator 103 receives the first reset signal RS1 and the delayed reset signal DL1. In a state the first reset signal RS1 is not input and the delayed reset signal DL1 is input, the return reset signal generator 103 discriminates the relevant state and outputs a return reset signal RS3. A case where the first reset signal RS1 is not output and the delayed reset signal DL1 is output is when the output of the first reset signal RS1 is terminated. In other words, when the power supply voltage Vdd once lowers to lower than or equal to the threshold voltage V₁ and again recovers to be higher than or equal to the threshold voltage V₁, the return reset delay signal RS3 is output for a constant period. Therefore, if the first reset signal RS1 is output, the return reset signal RS3 is output at the termination of the output of the first reset signal RS1.

The resetting device 104 is a device that is reset when the delayed reset signal DL1 is input. The resetting device 104 includes a device having a possibility of causing abnormal operation unless reset at a relatively high voltage such as a motor and a liquid crystal display. Resetting refers to initialization of the device, and indicates setting the register in the device to an initial value defined in advance. The resetting device 104 is reset at the time of power down, so that abnormal operation, breakage, and the like of the resetting device 104 can be prevented.

The second circuit block 200 preferably includes a reset signal generator 201, an AND circuit 202, a saving unit 203, a resetting device 204, a volatile storage device 205, and a nonvolatile storage device 206. The reset signal generator 201 is a reset IC arranged and programmed to monitor the power supply voltage Vc generated by the DC to DC converter 20. A second reset signal RS2 is output when the power supply voltage Vc lowers to a threshold voltage V₃ due to reasons such as shutting of power supply. The power supply voltage Vdd monitored by the reset signal generator 101 lowers to the threshold voltage V₂ while the power supply voltage Vc lowers to the threshold voltage V₃. V₂ is a threshold voltage lower than V. If a difference is created between the threshold voltages V₁, V₂, a predetermined time difference (t₄−t₃) can be ensured from when the reset signal generator 101 outputs the first reset signal RS1 until the reset signal generator 201 outputs the reset signal RS2, so that the data can be saved in the nonvolatile storage device 206 during such a period. The second reset signal RS2 is also low active.

Specific set examples of each power supply voltage and the threshold voltage include having the normal voltages V₀, V₁₀ of the normal power supply voltages Vdd and Vc at 12V, 3.3V, and the values of the threshold voltage V₁, the threshold voltage V₂, and the threshold voltage V₃ at 9V, 4V, and 3V.

The AND circuit 202 is a logical gate that outputs the reset signal if the reset signal is input to at least one of the two input units, and that does not output the reset signal if the reset signal is not input to either of the two input units. The AND circuit 202 outputs a logical sum reset signal RS4 to the saving unit 203 and the resetting device 204 when the return reset signal RS3 is input from the return reset signal generator 103. The logical sum signal RS4 is also input to the saving unit 203 and the resetting device 204 even when the second reset signal RS2 is input from the reset signal generator 201.

The resetting device 204 is a device that is reset when the logical sum reset signal RS4 is input. The resetting device 204 is preferably configured by a device that normally operates if the supplied power supply voltage Vc is greater than or equal to the voltage V₃ since the timing of reset is delayed compared to the resetting device 104. A device related to the preliminary process of resetting may also be arranged. The preliminary process of resetting is a process for preventing drawbacks and problems that occur when the device is immediately reset at the time of power down, and includes saving the data in the volatile storage device to the nonvolatile storage device, or terminating the write process of the flash memory to prevent corruption of data of the flash memory when the write device is reset during write of the flash memory. The preliminary process of resetting also includes preventing breakage of the hard disk drive when the reading head hits the disk due to an impact, by returning the head of the hard disk to the standby position.

The volatile storage device 205 is a storage device in which the held data is lost when the supply of power is stopped, and includes a synchronous dynamic random access memory (SDRAM). The data includes data inside the central processing unit (CPU), and the like. The nonvolatile storage device 206 is a storage device in which the data remains held even when the supply of power is stopped, and includes a flash memory, a hard disk drive, and the like. The nonvolatile storage device 206 also includes a storage device capable of holding data by attaching a battery to the volatile storage device, even when the supply of power is stopped.

The saving unit 203 saves the data held in the volatile storage device 205 to the nonvolatile storage device 206 based on the first reset signal RS1. The saving unit 203, which is a arithmetic processing unit, uses the first reset signal RS1 as a trigger to start saving. The data held in the volatile storage device 205 such as the data of the operation state of the electronic device 1, and the like is prevented from being lost by the stopping of power supply by saving the data. The saving unit 203 is reset when the logical sum reset signal RS4 is input from the AND circuit 202 to the saving unit 203. The saving unit 203 thus saves data from when the first reset signal RS1 is input until the logical sum reset signal RS4 is input. The saving unit 203 and the resetting device 204 are reset after the data are saved, so that the abnormal operation etc. of the saving unit 203 in the low voltage state can be prevented.

The reset signal generator 101 outputs the first reset signal RS1 when the power supply voltage Vdd lowers to the threshold voltage V₁, and the saving unit 203 starts to save the data based on the first reset signal RS1. The reset signal generator 201 outputs the second reset signal RS2 when the power supply voltage Vdd lowers to the threshold voltage V₂, and the saving unit 203 is reset based on the second reset signal RS2. Therefore, the saving unit 203 can save the data while the power supply voltage Vdd lowers from V₁ to V₂, and a period sufficient for saving data can be ensured.

The saving unit 203 and the resetting device 204 are reset based on the return reset signal RS3 output from the return reset signal generator 103. The reset signal generator 201 does not output the second reset signal RS2 even when the power supply voltage Vdd lowers to be lower than or equal to the threshold voltage V₁ if the power supply voltage Vdd recovers without lowering to the threshold voltage V₂. However, since lowering of the power supply voltage Vdd to be lower than or equal to the threshold voltage V₁ means that some kind of abnormality occurred in the power supply or the electronic device 1, the saving unit 203 and the resetting device 204 need to be reset after the process of saving data is terminated. Thus, the saving unit 203 and the resetting device 204 are reset based on the return reset signal RS3 output from the return reset signal generator 103 even if the power supply voltage Vdd lowers to be lower than or equal to the threshold voltage V₁ and recovers without lowering to the threshold voltage V₂. Therefore, the saving unit 203 and the resetting device 204 are reset when the reset signal generator 101 outputs the first reset signal RS1.

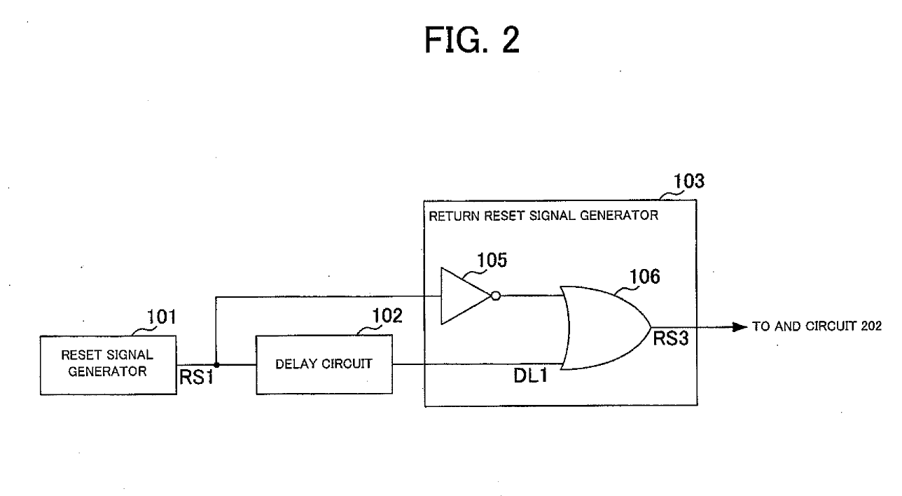

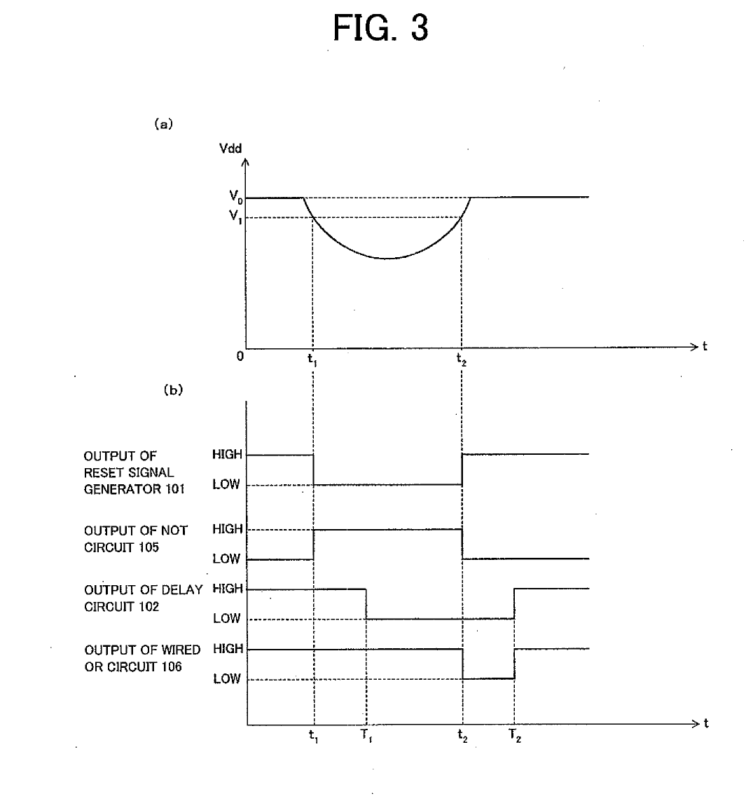

FIG. 2 is a block diagram illustrating one configuration example of the return reset signal generator 103 illustrated in FIG. 1. The return reset signal generator 103 is configured by a NOT circuit 105 and a wired OR circuit 106. The operation of the return reset signal generator 103 will be described below using the graph of FIG. 3.

FIG. 3 is a graph indicating the voltage change of each output terminal of the reset signal generator 101, the NOT circuit 105, the delay circuit 102, and the wired OR circuit 106 in FIG. 2 of a case where the power supply voltage Vdd is lowered. FIG. 3(a) illustrates the potential change of the power supply voltage Vdd, and FIG. 3(b) illustrates the switch between the high level and the low level of each output terminal. The horizontal axis of FIG. 3(a) and FIG. 3(b) indicates time t. A case where the power supply voltage Vdd temporarily lowers, the power supply voltage Vdd becomes lower than or equal to the threshold voltage V₁ from time t₁ to t₂, and the power supply voltage Vdd recovers to greater than or equal to the threshold voltage V₁ at time t₂, as illustrated in FIG. 3(a), will be described. The first reset signal RS1 is a low active signal, where the first reset signal RS1 is output when the output terminal is in the low level state in the graph indicating the potential change of the output terminal of the reset signal generator 101 of FIG. 3(b). The first reset signal RS1 is not output when the output terminal of the reset signal generator 101 is in the high level state.

When the power supply voltage Vdd becomes lower than or equal to V₁ at time t₁, the reset signal generator 101 detects change in the power supply voltage Vdd, and outputs the first reset signal RS1. The output of the first reset signal generator 101 is high level in the normal state, and switches from high level to low level at time t₁. When the power supply voltage again recovers to greater than or equal to V₁ at time t₂, the output of the first reset signal RS1 is terminated, and the output of the first reset signal generator 101 switches from low level to high level.

As illustrated in FIG. 2, the first reset signal RS1 is input to the wired OR circuit 106 through the NOT circuit 105 or the delay circuit 102. The NOT circuit 105 is a negate circuit in which the output is high level if the input terminal is low level, and the output is low level if the input terminal is high level. When the output signal from the reset signal generator 101 passes the NOT circuit 105, the low level and the high level of the output signal from the reset signal generator 101 are inverted, as illustrated in the graph at the time of output of the NOT circuit 105 of FIG. 3(b). Therefore, the output of the NOT circuit 105 is low level in the normal state, and changes from low level to high level at time t₁. The output changes from high level to low level at time t₂.

The first reset signal RS1 is input to the wired OR circuit 106 with the start and end timing of the output delayed by the delay circuit 102. Therefore, the output DL1 of the delay circuit 102 is such that the output of the reset signal generator 101 is delayed by a predetermined period by the delay circuit 102. Therefore, the output of the delay circuit 102 changes from high level to low level at time T₂, delayed by a constant period from time t₁. The output changes from low level to high level at time T₂, delayed by a constant period from time t₂.

The wired OR circuit 106 is a logical gate in which the output RS3 is low level if the two input terminals are both low level, and the output RS3 is high level if at least one of the input terminals is high level. The output of the wired OR circuit 106 is high level if at least one of the output of the NOT circuit 105 or the output of the delay circuit 102 is high level. The output of the wired OR circuit 106 is low level and the return reset signal RS3 is output if both the output of the NOT circuit 105 and the output of the delay circuit 102 are low level.

As illustrated in the graph at the time of output of the NOT circuit 105 and the output of the delay circuit 102 of FIG. 3(b), the reset signal generator 101 terminates the output of the first reset signal RS1 at the timing the power supply voltage Vdd recovers to greater than or equal to the threshold voltage V. Thus, the output of the NOT circuit 105 switches from high level to low level at time t₂. However, the output of the delay circuit 102 remains at low level during a period from time t₂ to T₂ even when the output of the first reset signal is terminated as the switch from the low level to the high level of the output is delayed. The wired OR circuit 106 outputs the return reset signal RS3 since the two input terminals are both low level from time t₂ to T₂. That is, the return reset signal RS3 is output when the power supply voltage Vdd once lowers to be lower than or equal to V₁, and then again recovers to greater than or equal to V₁, as illustrated in FIG. 3(a).

As described in FIG. 1, when the return reset signal RS3 is output, the logical sum reset signal RS4 is input to the saving unit 203 and the resetting device 204, and the saving unit 203 and the resetting device 204 are reset. Thus, the saving unit 203 and the resetting device 204 are reset at the recovery of the power supply voltage Vdd even if the reset signal generator 201 does not output the second reset signal RS2, and the abnormal operation, etc., that arises when the saving unit 203 and the resetting device 204 are not reset can be prevented.

Therefore, the return reset signal generator 103 prevents the saving unit 203 and the resetting device 204 from being immediately reset by the input first reset signal RS1, and ensures the provision of a period for saving data. The return reset signal generator 103 outputs the return reset signal RS3 to the AND circuit 202 when the output of the first reset signal RS1 is terminated, and resets the saving unit 203 and the resetting device 204.

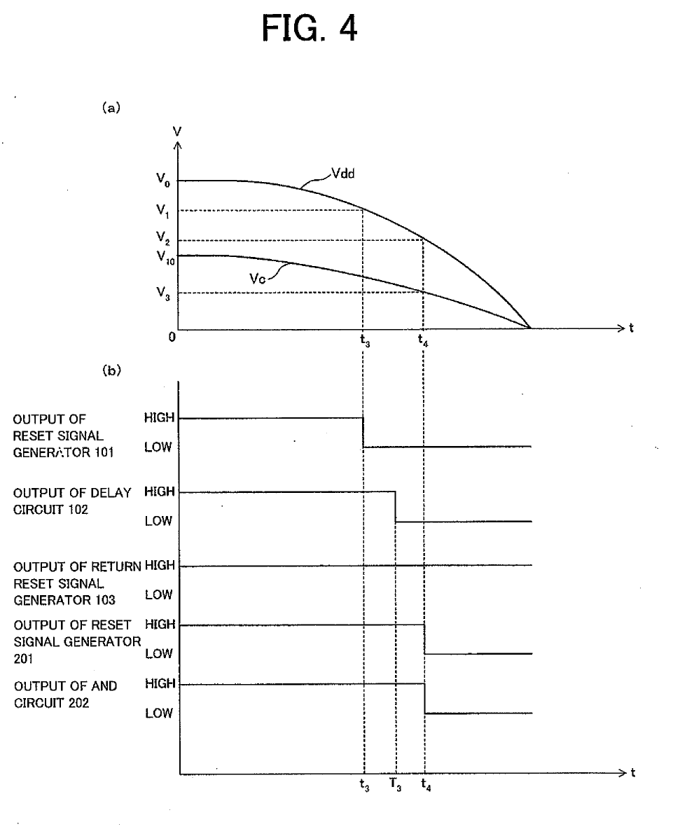

FIG. 4 is a timing chart illustrating the potential change of each output of the reset signal generator 101, the delay circuit 102, the return reset signal generator 103, the reset signal generator 201, and the AND circuit 202 of FIG. 1 in a case where the power supply voltage Vdd of FIG. 1 is changed. FIG. 4(a) is a graph indicating change in the power supply voltage Vdd and the power supply voltage Vc. The vertical axis of FIG. 4(a) indicates voltage V, and the horizontal axis indicates time t. The vertical axis of FIG. 4(b) indicates the potential change of each output of the reset signal generation unit 101, the delay circuit 102, the return reset signal generation unit 103, the reset signal generator 201, and the AND circuit 202, and the horizontal axis indicates time t. A case where the power supply voltage Vdd gradually lowers from the initial voltage V₀, and lowers to 0V will be described as a specific example.

When the power supply voltage Vdd becomes lower than or equal to V₁ at time t₃, the reset signal generator 101 outputs the first reset signal RS1, and the output of the reset signal generator 101 changes from high level to low level. The potential of the output DL1 of the delay circuit 102 changes from high level to low level at time T₃, delayed by a predetermined period from the output of the reset signal generator 101. In this case, the delay reset signal DL1 is input to the resetting device 104, and the resetting device 104 is reset.

The return reset signal generator 103 does not output the return reset signal RS3 if the power supply voltage Vdd does not recover to greater than or equal to the threshold voltage V. Thus, the output of the return reset signal generator 103 is always at high level, as illustrated in FIG. 4(b).

The power of the power supply voltage Vc is supplied to the reset signal generator 201. As illustrated in FIG. 4(a), when the power supply voltage Vdd supplied to the DC to DC converter 20 lowers, the power supply voltage Vc output from the DC to DC converter 20 to the reset signal generator 201 also lowers. When the power supply voltage Vc lowers from the normal voltage V₁₀ to the threshold voltage V₃, the reset signal generator 201 outputs the second reset signal RS2, and the output of the reset signal generator 201 changes from high level to low level. In this case, the power supply voltage Vdd is lowered from the initial voltage V₀ to the threshold voltage V₂. In other words, the second reset signal RS2 is output when the power supply voltage Vdd lowers to the threshold voltage V₂.

The AND circuit 202 is such that the output is low level if at least one of the two input terminals is low level. Therefore, the logical sum reset signal RS4 is output when one of the outputs of the reset signal generator 201 or of the return reset signal generator 103 is low level. In FIG. 4(b), the output of the return reset signal generator 103 is always high level, but the second reset signal RS2 is output at time t₄. Thus, the logical sum reset signal RS4 is output at time t₄, and the output of the AND circuit 202 changes from high level to low level.

As described above, when the power supply voltage Vdd lowers, the data held in the volatile storage device 205 starts to be saved by the saving unit 203, and the resetting device 104 is reset if the power supply voltage Vdd lowers to be lower than or equal to the threshold voltage V. The saving unit 203 and the resetting device 204 are reset when the power supply voltage Vdd lowers to be lower than or equal to the threshold voltage V₂. Therefore, the saving unit 203 can save the data while the power supply voltage Vdd lowers from voltage V₁ to V₂ or from time t₃ to t₄ in FIG. 4. Thus, a period sufficient for the saving unit 203 to save the data held in the volatile storage device 205 to the nonvolatile storage device 206 can be ensured.

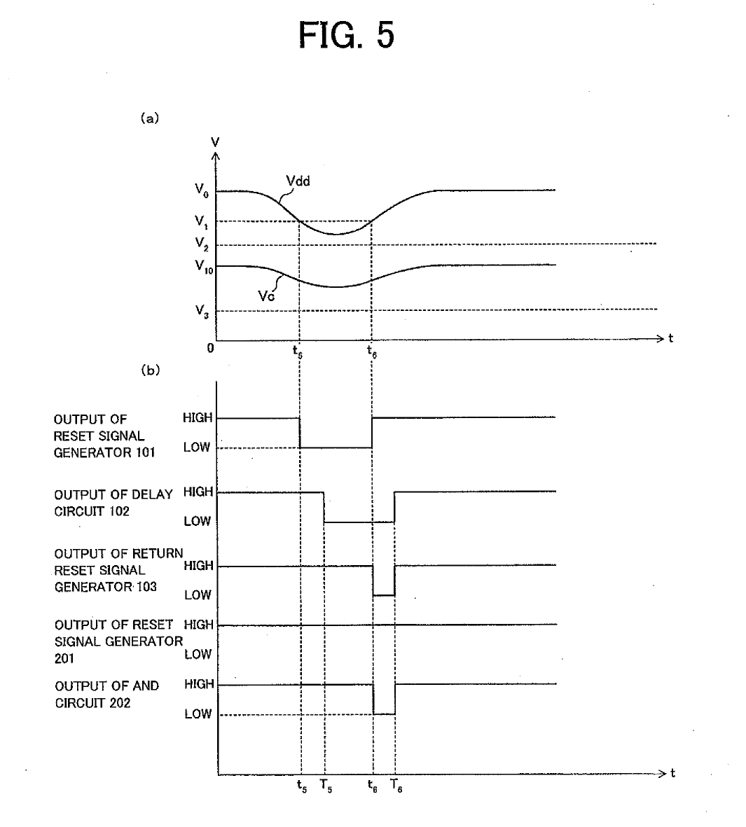

Similar to FIG. 4, FIG. 5 is a timing chart illustrating the voltage change of each output of the reset signal generator 101, the delay circuit 102, the return reset signal generator 103, the reset signal generator 201, and the AND circuit 202 of FIG. 1. FIG. 5 illustrates a case where the power supply voltage Vdd lowers to be lower than or equal to the threshold voltage V₁ at time t₅ but recovers to greater than or equal to the threshold voltage V₁ at time t₆ without lowering to be lower than or equal to the threshold voltage V₂. FIG. 5(a) is a graph indicating change in the power supply voltage Vdd and the power supply voltage Vc, where the vertical axis indicates voltage V and the horizontal axis indicates time t.

The vertical axis of FIG. 5(b) indicates the potential change of each output of the reset signal generator 101, the delay circuit 102, the return reset signal generator 103, the reset signal generator 201, and the AND circuit 202, and the horizontal axis indicates time t. The output of the reset signal generator 101 changes from high level to low level at time t₅, and changes from low level to high level at time t₆. The output of the delay circuit 102 is obtained by delaying the output of the reset signal generator 101, which changes from high level to low level at time T₅, delayed by a constant period from time t₅, and changes from low level to high level at time T₆, delayed by a constant period from time t₆.

The return reset signal RS3 is output during a period in which the output of the reset signal generator 101 is high level and the output of the delay circuit 102 is low level. Therefore, as illustrated in the timing chart of the output of the reset signal generator 101 and the delay circuit 102 of FIG. 5(b), the return reset signal RS3 is output during the period from time t₆ to T₆. The period from time t₆ to T₆ corresponds to the delay period of the delay circuit 102.

The second reset signal RS2 is output when the power supply voltage Vc lowers to be lower than or equal to the threshold voltage V₃, that is, when the power supply voltage Vdd lowers to be lower than or equal to the threshold voltage V₂. In the graph of FIG. 5(a), the output of the reset signal generator 201 is always at high level since the power supply voltage Vc does not lower to be lower than or equal to the voltage V₃. The logical sum reset signal RS4 is output during a period the second reset signal RS2 or the return reset signal RS3 is output. Thus, the logical sum reset signal RS4 is output and the output of the AND circuit 202 becomes low level during the period from t₆ to T₆ in which the return reset signal RS3 is output.

In the example of FIG. 4, the second reset signal RS2 is output and the saving unit 203 and the resetting device 204 are reset when the power supply voltage Vdd lowers to be lower than or equal to the threshold voltage V₂. In the example of FIG. 5, the second reset signal RS2 is not output since the power supply voltage Vdd does not lower to be lower than or equal to the threshold voltage V₂. In this case as well, the return reset signal RS3 is output when the power supply voltage Vdd recovers to greater than or equal to the threshold voltage V₁, and the saving unit 203 and the resetting device 204 are reset based on the return reset signal RS3.

Thus, when the power supply voltage Vdd lowers to be lower than or equal to the threshold voltage V₁, the logical sum reset signal RS4 is output and the saving unit 203 and the resetting device 204 are reset even if the power supply voltage Vdd does not lower to be lower than or equal to the threshold voltage V₂. The saving unit 203 can save the data held in the volatile storage device 205 to the nonvolatile storage device 206 until the output of the first reset signal RS1 is terminated with the first reset signal RS1 as a trigger. In the example of FIG. 5, the data can be saved in the nonvolatile storage device 206 from time t₅ to t₆ in the example of FIG. 5.

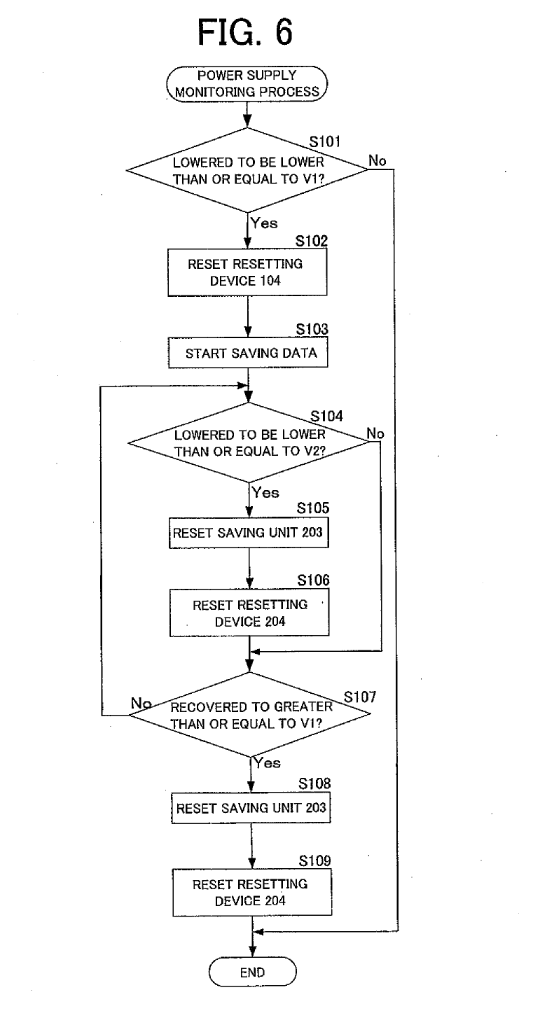

The steps S101 to S109 of FIG. 6 are flow charts illustrating one example of a power supply monitoring process in the electronic device 1 of FIG. 1. First, the reset signal generator 101 monitors whether the power supply voltage Vdd lowered to be lower than or equal to the threshold voltage V₁ (step S101). If the power supply voltage Vdd lowered to be lower than or equal to V₁, the reset signal generator 101 outputs the first reset signal RS1, and the resetting device 104 is reset based on the first reset signal RS1 (step S102). The saving unit 203 starts to save the data held in the volatile storage device 205 to the nonvolatile storage device 206 when the first reset signal RS1 is input (step S103). The process is terminated if the power supply voltage Vdd is higher than the threshold voltage V₁ in the determination of step S101.

The reset signal generator 201 monitors the power supply voltage Vc (step S104). The reset signal generator 201 outputs the second reset signal RS2 if the power supply voltage Vc is lower than or equal to the threshold voltage V₃, that is, if the power supply voltage Vdd is lower than or equal to the threshold voltage V₂. The saving unit 203 and the resetting device 204 are reset based on the second reset signal RS2 (step S105, step S106).

Whether the power supply voltage Vdd recovered to greater than or equal to the threshold voltage V₁ is determined by the reset signal generator 101 (step S107). If the power supply voltage Vdd recovered to greater than or equal to the voltage V₁, the return reset signal generator 103 outputs the return reset signal RS3. The saving unit 203 and the resetting device 204 are reset based on the return reset signal RS3 (step S108, step S109), and then the process is terminated. If the power supply voltage Vc is higher than the threshold voltage V₃, that is, if the power supply voltage Vdd is higher than the threshold voltage V₂ in the determination of step S104, the processes of step S105 and step S106 are not performed and the determination of step S107 is performed.

If the power supply voltage Vdd is not recovered to greater than or equal to the threshold voltage V₁ in the determination of step S107, the determination of step S104 is again carried out. Therefore, if the power supply voltage Vdd lowers to be lower than or equal to the threshold voltage V₁, the resetting of the saving unit 203 in step S108 and the resetting of the resetting device 204 in step S109 are performed regardless of the comparison result of the power supply voltage Vdd and the threshold voltage V₂ in step S104.

In the present preferred embodiment, high threshold voltage V₁ is preferably supplied to the resetting device 104 to enable reset at an early stage, and low threshold voltage V₂ is supplied to the saving unit 203 and the resetting device 204 to delay the reset. The saving unit 203 starts to save the data with the first rest signal RS1 used in the resetting of the resetting device 104 as a trigger, so that the period for saving the data can be ensured. Thus, a period sufficient to save the data even if the nonvolatile storage device 206 has a low access speed such as a hard disk drive can be ensured.

If the reset signal generator 201 does not output the reset signal, the saving unit 203 and the resetting device 204 are reset by the reset signal output by the reset signal generator 101. Thus, as one threshold of the two reset signal generators having different thresholds is set low, a situation where reset is not performed even if abnormality of the power supply occurs can be prevented.

In the present preferred embodiment, a case where the threshold voltage at which to output the first reset signal RS1 of the reset signal generator 101 and the threshold voltage at which to terminate the output of the reset signal RS1 preferably are the same has been described, but the present invention is not limited thereto. The threshold voltage at which to output the first reset signal RS1 of the reset signal generator 101 and the threshold voltage at which to terminate the output of the first reset signal RS1 may be different.

In the present preferred embodiment, a case where the saving unit 203 preferably saves the data stored in the volatile storage device 205 has been described as an example of the preliminary process of resetting, but the present invention is not limited to a case of saving data. For instance, the process in which saving unit 203 returns the magnetic head of the hard disk drive to the standby position to prevent breakage of the hard disk drive by power down based on the first reset signal RS1 may be carried out for the preliminary process of resetting.

In the present preferred embodiment, an example in which the return reset signal generator 103 is preferably configured by the NOT circuit 105 and the wired OR circuit has been described, but the present invention is not limited thereto. For instance, an application specific integrated circuit (ASIC) may be arranged between the delay circuit 102 and the wired OR circuit 106 of FIG. 2, and the ASIC may output the input delay reset signal DL1 as is, or may be configured to switch so that the first reset signal RS1 of the reset signal generator 101 is input to the saving unit 203 and the resetting device 204 by the change in setting of the ASIC. Alternatively, the wired OR circuit may be a normal OR circuit.

In the present preferred embodiment, a case where the resetting device 104 is preferably reset when the delay reset signal DL1 is input has been described, but the present invention is not limited thereto. The resetting device 104 may be reset when the first reset signal RS1 is input.

While the present invention has been described with respect to preferred embodiments thereof, it will be apparent to those skilled in the art that the disclosed invention may be modified in numerous ways and may assume many preferred embodiments other than those specifically set out and described above. Accordingly, the appended claims cover all modifications that fall within the true spirit and scope of the present invention.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. An electronic device comprising:
a first reset signal generator arranged to output a first reset signal when a power supply voltage becomes lower than or equal to a first threshold;
a second reset signal generator arranged to output a second reset signal when the power supply voltage becomes lower than or equal to a second threshold lower than the first threshold;
a return reset signal generator arranged to output a return reset signal based on a termination of the output of the first reset signal;
a first resetting device arranged to be reset based on the first reset signal;
a second resetting device arranged to be reset based on the second reset signal and the return reset signal; and
a pre-processor arranged in the second resetting device to start a preliminary process of resetting based on the first reset signal.

2. The electronic device according to claim 1, wherein the pre-processor is arranged to start to save data held in a volatile storage device to a nonvolatile storage device based on the first reset signal.

3. The electronic device according to claim 1, wherein the return reset signal generator is arranged to output the return reset signal for a constant period from a termination of the output of the first reset signal using a delay circuit.

4. The electronic device according to claim 3, wherein the return reset signal generator includes a negate circuit arranged to invert the first reset signal and an OR circuit arranged to receive an output signal of the negate circuit and an output signal of the delay circuit, and to output the return reset signal from the OR circuit.

5. The electronic device according to claim 1, further comprising an AND circuit arranged to receive the second reset signal and the return reset signal and to output a logical sum reset signal, wherein the second resetting device is reset based on the logical sum reset signal.

6. An electronic device comprising:
means for outputting a first reset signal when a power supply voltage becomes lower than or equal to a first threshold;
means for outputting a second reset signal when the power supply voltage becomes lower than or equal to a second threshold lower than the first threshold;
means for outputting a return reset signal based on a termination of the output of the first reset signal;
a first resetting device arranged to be reset based on the first reset signal;
a second resetting device arranged to be reset based on the second reset signal and the return reset signal; and
means for starting a preliminary process of resetting based on the first reset signal.

7. The electronic device according to claim 6, further comprising means for starting to save data held in a volatile storage device to a nonvolatile storage device based on the first reset signal.

8. The electronic device according to claim 6, further comprising means for outputting a return reset signal for a constant period from a termination of the output of a delayed first reset signal.

9. The electronic device according to claim 8, further comprising:
means for inverting the first reset signal; and
means for taking a logical sum of the inverted first reset signal and an output signal from a delay circuit, and outputting the return reset signal.

10. The electronic device according to claim 6, further comprising:
means for generating a logical sum signal from the second reset signal and the return reset signal; and
means for resetting the second resetting device based on the logical sum reset signal.
